(19) United States
(12) Patent Application Publication
(10) Pub. No.: US 2025/0246577 A1
(43) Pub. Date: Jul. 31, 2025

(54) DOUBLE-SIDED HEAT DISSIPATION SEMICONDUCTOR PACKAGE AND METHOD OF MANUFACTURING THE SAME

(71) Applicant: JMJ Korea Co., Ltd., Busan (KR)

(72) Inventor: Yun Hwa CHOI, Busan (KR)

(73) Assignee: JMJ Korea Co., Ltd., Busan (KR)

(21) Appl. No.: 18/743,099

(22) Filed: Jun. 13, 2024

(30) Foreign Application Priority Data
Jan. 26, 2024 (KR) 10-2024-0012594

(51) Int. Cl. H01L 23/00; H01L 23/31; H01L 23/498; H01L 25/065

(52) U.S. Cl. CPC H01L 24/92; H01L 23/49822; H01L 24/29; H01L 24/30; H01L 23/3107; H01L 23/49811; H01L 25/0655; H01L 2224/29111; H01L 2224/29139; H01L 2224/29147; H01L 2224/30505; H01L 2224/9202

(57) ABSTRACT

The present invention relates to a double-sided heat dissipation semiconductor package and a method of manufacturing the same, and more particularly, to a double-sided heat dissipation semiconductor package and a method of manufacturing the same in which re-meltdown or generation of cracks in bonding members during sequential bonding processes may be suppressed to increase its quality.

### CROSS-REFERENCE TO RELATED PATENT APPLICATION

This application claims the benefit of Korean Patent Application No. 10-2024-0012594, filed on Jan. 26, 2024, in the Korean Intellectual Property Office, the disclosure of which is incorporated herein in its entirety by reference.

### BACKGROUND OF THE INVENTION

### Field of the Invention

The present invention relates to a double-sided heat dissipation semiconductor package and a method of manufacturing the same, and more particularly, to a double-sided heat dissipation semiconductor package and a method of manufacturing the same in which re-meltdown or generation of cracks in bonding members during sequential bonding processes may be suppressed to increase its quality.

### Description of the Related Art

In general, a semiconductor package includes semiconductor chips installed on a lower substrate or an upper substrate, conductors which are metal posts functioning as spacers bonded on the semiconductor chips, a lead frame which is formed of Cu and applies external electrical signals, and a package housing molded by a sealing member. Here, the semiconductor chips are bonded on a pad of the lead frame and a plating layer formed of Ag is interposed between the semiconductor chip and the lead frame so that a lead of the lead frame is electrically connected to a pad of the semiconductor chip by using a bonding wire which is a signal line.

For example, as illustrated in FIG. 1A, in a general semiconductor package, semiconductor chips 14 are bonded on a lower metal insulating substrate 11A by using first bonding members 12 interposed therebetween, hexahedral or cylindrical conductors 17 having vertical structures which are metal spacers are bonded on the semiconductor chips 14 by using second bonding members 16 interposed therebetween and are bonded on an upper metal insulating substrate 11B by using third bonding members 13 interposed therebetween, and a metal bridge 18 having a vertical structure is formed for electrical connection between the lower metal insulating substrate 11A and the upper metal insulating substrate 11B.

The semiconductor chips are bonded to the substrates and the conductors by using solders. However, cracks may be generated in the first bonding members 12 or the second bonding members 16 due to each different Coefficient of Thermal Expansion (CTE) between the substrates 11A and 11B, the conductors 17, the first bonding members 12, and the second bonding members 16 as illustrated in FIG. 1B so that reliability problems may occur.

Meanwhile, in a bonding process, the hardening temperature may be lowered as a following process progresses. However, in the following process, when the bonding member bonded in the preceding process is a solder, the solder may be re-melted down. Also, when the bonding member is a sinter or epoxy, cracks may be generated and thereby, bonding may be broken so that quality may be degraded.

In this regard, there is a demand for the development of a technology that may suppress re-meltdown or generation of cracks in bonding members during a sequential bonding process.

### SUMMARY OF THE INVENTION

The present invention provides a double-sided heat dissipation semiconductor package and a method of manufacturing the same in which re-meltdown or generation of cracks in bonding members during sequential bonding processes may be suppressed to increase its quality.

According to an aspect of the present invention, there is provided a double-sided heat dissipation semiconductor package including: at least one lower substrate comprising at least one metal pattern; at least one upper substrate including at least one metal pattern disposed to face the lower substrates and spaced apart from the lower substrates; at least one semiconductor device including one surface bonded to the lower substrate, the upper substrate, or both lower substrate and upper substrate by using first bonding members interposed therebetween; at least one semiconductor component including one surface bonded to the lower substrate, the upper substrate, or both lower substrate and upper substrate by using fourth bonding members interposed therebetween; at least one first electrical connection member including one surface bonded to the other surface of the at least one semiconductor device by using second bonding members interposed therebetween and the other surface bonded to the lower substrate, the upper substrate, or both lower substrate and upper substrate by using third bonding members interposed therebetween; at least one second electrical connection member electrically connected to the at least one semiconductor device; a package housing covering the at least one semiconductor device and the at least one semiconductor component; and at least one terminal lead bonded to the lower substrate, the upper substrate, or both lower substrate and upper substrate by using fifth bonding members interposed therebetween and partially or entirely exposed to the outside of the package housing, wherein when bonding processes of the first bonding members and the third bonding members are performed, the boning temperature or bonding materials of the first bonding members and the third bonding members are different from each other and when bonding processes of the third bonding members and the fifth bonding members are performed, the boning temperature or bonding materials of the third bonding members and the fifth bonding members are same as each other.

Here, at least any one of the first bonding members through the fifth bonding members may be a solder containing Sn or an adhesive containing 55% or more of Ag or Cu.

Here, when at least any one of the first bonding members through the fifth bonding members is a solder, the melting temperature of the solder may be 180° C. through 500° C.

Also, when at least any one of the first bonding members through the fifth bonding members is an adhesive, the adhesive may be bonded by pressurizing or non-pressure sintering or epoxy included in the adhesive may be hardened to bond the adhesive.

Also, the semiconductor component may be firstly bonded to the lower substrate or the upper substrate by using the fourth bonding members, the semiconductor devices may be secondly bonded to the lower substrate or the upper substrate by using the first bonding members and the first electrical connection members may be secondly bonded to the semiconductor devices by using the second bonding members at the same time, the bonding materials or the bonding temperature of the first bonding members and the second bonding members may be same as each other and may be different from those of the fourth bonding members, the other surfaces of the first electrical connection members may be thirdly bonded to the lower substrate or the upper substrate by using the third bonding members and the terminal leads may be thirdly bonded to the lower substrate or the upper substrate by using the fifth bonding members at the same time, and the bonding materials or the bonding temperature of the third bonding members and the fifth bonding members may be same as each other and are different from those of the first bonding members and the second bonding members.

Also, the semiconductor devices may be firstly bonded to the lower substrate or the upper substrate by using the first bonding members, one surfaces of the first electrical connection members may be firstly bonded to the semiconductor devices by using the second bonding members, and the semiconductor components may be firstly bonded to the lower substrate or the upper substrate by using the fourth bonding members at the same time, the bonding materials or the bonding temperature of the first bonding members, the second bonding members, and the fourth bonding members may be same as each other, the other surfaces of the first electrical connection members may be secondly bonded to the lower substrate or the upper substrate by using the third bonding members and the terminal leads may be secondly bonded to the lower substrate or the upper substrate by using the fifth bonding members at the same time, and the bonding materials or the bonding temperature of the third bonding members and the fifth bonding members may be same as each other and may be different from those of the first bonding members, the second bonding members, and the fourth bonding members.

Also, the semiconductor components may be firstly bonded to the lower substrate or the upper substrate by using the fourth bonding members and the semiconductor devices may be firstly bonded to the lower substrate or the upper substrate by using the first bonding members at the same time, one surfaces of the first electrical connection members may be secondly bonded to the other surfaces of the semiconductor devices by using the second bonding members, the bonding materials or the bonding temperature of the second bonding members may be different from those of the first bonding members and the fourth bonding members, the other surfaces of the first electrical connection members may be thirdly bonded to the lower substrate or the upper substrate by using the third bonding members and the terminal leads may be thirdly bonded to the lower substrate or the upper substrate by using the fifth bonding members at the same time, and the bonding materials or the bonding temperature of the third bonding members and the fifth bonding members may be same as each other and are different from those of the first bonding members, the second bonding members, and the fourth bonding members.

Also, the semiconductor devices may be firstly bonded to the lower substrate or the upper substrate by using the first bonding members, one surfaces of the first electrical connection members may be secondly bonded to the other surfaces of the semiconductor devices by using the second bonding members and the semiconductor components may be secondly bonded to the lower substrate or the upper substrate by using the fourth bonding members at the same time, the bonding materials or the bonding temperature of the second bonding members and the fourth bonding members may be same as each other and are different from those of the first bonding members, the other surfaces of the first electrical connection members may be thirdly bonded to the lower substrate or the upper substrate by using the third bonding members and the terminal leads may be thirdly bonded to the lower substrate or the upper substrate by using the fifth bonding members at the same time, and the bonding materials or the bonding temperature of the third bonding members and the fifth bonding members may be same as each other and may be different from those of the second bonding members and the fourth bonding members.

Also, the lower substrate or the upper substrate may include at least one insulating layer and a thickness of the metal pattern may be greater than a thickness of the insulating layer.

Here, the thickness of the insulating layer may be 0.2 mm through 0.35 mm.

Also, the insulating layer may be Al₂O₃, ZTA, AlN, or Si₃N₄.

Also, the semiconductor component may be a Negative Temperature Coefficient Thermistor (NTC).

Also, the third bonding members and the fourth bonding members may include solder ingredients and the melting point of the third bonding members may be lower than the melting point of the fourth bonding members.

Also, the third bonding members and the fifth bonding members may include solder ingredients and may have the same melting point.

Also, the fifth bonding members used to bond the terminal leads may be solder adhesives containing epoxy ingredients and epoxy may be included on the surfaces of the solders or in at least a part of the solder after the fifth bonding members and the terminal leads are bonded to each other by soldering.

Also, the second electrical connection members may contain 50% or more of Al and may be bonded to the semiconductor devices by using an ultrasonic bonding method.

Also, one surfaces and the other surfaces of the semiconductor devices may be formed of a metal containing 80% or more of Au or Ag.

Also, the terminal leads may partially or entirely contain Al.

Also, the lower substrate or the upper substrate may be partially or entirely exposed to the surface of the package housing.

Also, the terminal leads may have the surfaces partially or entirely coated with Sn.

Also, the lower substrate or the upper substrate may include pinfin which is structurally protruded for heat dissipation.

Also, the first electrical connection members may be spacers containing a hexahedral metal ingredient or metal clips in a clip form.

According to another aspect of the present invention, there is provided a method of manufacturing a double-sided heat dissipation semiconductor package including: a first step for preparing at least one lower substrate including at least one metal pattern and at least one upper substrate including at least one metal pattern disposed to face the lower substrates and spaced apart from the lower substrates; a second step for firstly bonding the at least one semiconductor component to the lower substrate or the upper substrate by using the fourth bonding members; a third step for secondly bonding the at least one semiconductor device to the lower substrate or the upper substrate by using the first bonding members and secondly bonding the at least one first electrical connection member to the semiconductor devices by using the second bonding members at the same time; a fourth step for testing electrical properties of the lower substrate and the upper substrate; a fifth step for thirdly bonding the first electrical connection members to the lower substrate or the upper substrate by using the third bonding members and thirdly bonding the at least one terminal lead to the lower substrate or the upper substrate by using the fifth bonding members at the same time; a sixth step for molding the at least one semiconductor device and the at least one semiconductor component to form the package housing; a seventh step for performing curing at a predetermined temperature for more than a predetermined time; an eighth step for plating the terminal leads; and a ninth step for individualizing a separate semiconductor package, wherein when the bonding processes of the first bonding members and the third bonding members are performed, the first bonding members and the third bonding members have each different bonding temperature or bonding materials and when the bonding processes of the third bonding members and the fifth bonding members are performed, the third bonding members and the fifth bonding members have the same bonding temperature or bonding materials.

According to another aspect of the present invention, there is provided a method of manufacturing a double-sided heat dissipation semiconductor package including: a first step for preparing at least one lower substrate including at least one metal pattern and at least one upper substrate including at least one metal pattern disposed to face the lower substrates and spaced apart from the lower substrates; a second step for firstly bonding the at least one semiconductor device to the lower substrate or the upper substrate by using the first bonding members, firstly bonding one surfaces of the at least one first electrical connection member to the at least one semiconductor device by using the second bonding members, and firstly bonding the at least one semiconductor component to the lower substrate or the upper substrate by using the fourth bonding members at the same time; a third step for testing electrical properties of the lower substrate and the upper substrate; a fourth step for secondly bonding the other surfaces of the first electrical connection members to the lower substrate or the upper substrate by using the third bonding members and secondly bonding the at least one terminal lead to the lower substrate or the upper substrate by using the fifth bonding members at the same time; a fifth step for molding the at least one semiconductor device and the at least one semiconductor component to form the package housing; a sixth step for performing curing at a predetermined temperature for more than a predetermined time; a seventh step for plating the terminal leads; and an eighth step for individualizing a separate semiconductor package, wherein when the bonding processes of the first bonding members and the third bonding members are performed, the first bonding members and the third bonding members have each different bonding temperature or bonding materials and when the bonding processes of the third bonding members and the fifth bonding members are performed, the third bonding members and the fifth bonding members have the same bonding temperature or bonding materials.

According to another aspect of the present invention, there is provided a method of manufacturing a double-sided heat dissipation semiconductor package including: first step for preparing at least one lower substrate including at least one metal pattern and at least one upper substrate including at least one metal pattern disposed to face the lower substrates and spaced apart from the lower substrates; a second step for firstly bonding the at least one semiconductor component to the lower substrate or the upper substrate by using the fourth bonding members and firstly bonding the at least one semiconductor device to the lower substrate or the upper substrate by using the first bonding members at the same time; a third step for secondly bonding the at least one first electrical connection member to the other surfaces of the semiconductor devices by using the second bonding members; a fourth step for testing electrical properties of the lower substrate and the upper substrate; a fifth step for thirdly bonding the other surfaces of the first electrical connection members to the lower substrate or the upper substrate by using the third bonding members and thirdly bonding the at least one terminal lead to the lower substrate or the upper substrate by using the fifth bonding members at the same time; a sixth step for molding the at least one semiconductor device and the at least one semiconductor component to form the package housing; a seventh step for performing curing at a predetermined temperature for more than a predetermined time; an eighth step for plating the terminal leads, and a ninth step for individualizing a separate semiconductor package, wherein when the bonding processes of the first bonding members and the third bonding members are performed, the first bonding members and the third bonding members have each different bonding temperature or bonding materials and when the bonding processes of the third bonding members and the fifth bonding members are performed, the third bonding members and the fifth bonding members have the same bonding temperature or bonding materials.

According to another aspect of the present invention, there is provided a method of manufacturing a double-sided heat dissipation semiconductor package including: first step for preparing at least one lower substrate including at least one metal pattern and at least one upper substrate including at least one metal pattern disposed to face the lower substrates and spaced apart from the lower substrates; a second step for firstly bonding the at least one semiconductor device to the lower substrate or the upper substrate by using the first bonding members; a third step for secondly bonding the at least one first electrical connection member to the other surfaces of the semiconductor devices by using the second bonding members and secondly bonding the semiconductor components to the lower substrate or the upper substrate by using the fourth bonding members at the same time; a fourth step for testing electrical properties of the lower substrate and the upper substrate; a fifth step for thirdly bonding the first electrical connection members to the lower substrate or the upper substrate by using the third bonding members and thirdly bonding the at least one terminal lead to the lower substrate or the upper substrate by using the fifth bonding members at the same time; a sixth step for molding the at least one semiconductor device and the at least one semiconductor component to form the package housing; a seventh step for performing curing at a predetermined temperature for more than a predetermined time; an eighth step for plating the terminal leads; and a ninth step for individualizing a separate semiconductor package, wherein when the bonding processes of the first bonding members and the third bonding members are performed, the first bonding members and the third bonding members have each different bonding temperature or bonding materials and when the bonding processes of the third bonding members and the fifth bonding members are performed, the third bonding members and the fifth bonding members have the same bonding temperature or bonding materials.

### BRIEF DESCRIPTION OF THE DRAWINGS

The above and other features and advantages of the present invention will become more apparent by describing in detail exemplary embodiments thereof with reference to the attached drawings in which:

FIGS. 1A and 1B are semiconductor packages according to a prior art;

FIG. 2 is a cross-sectional view of a double-sided heat dissipation semiconductor package according to a first embodiment of the present invention;

FIG. 3 is a flowchart illustrating a method of manufacturing a double-sided heat dissipation semiconductor package according to a second embodiment of the present invention;

FIG. 4 is a flowchart illustrating a method of manufacturing a double-sided heat dissipation semiconductor package according to a third embodiment of the present invention;

FIG. 5 is a flowchart illustrating a method of manufacturing a double-sided heat dissipation semiconductor package according to a fourth embodiment of the present invention; and

FIG. 6 is a flowchart illustrating a method of manufacturing a double-sided heat dissipation semiconductor package according to a fifth embodiment of the present invention.

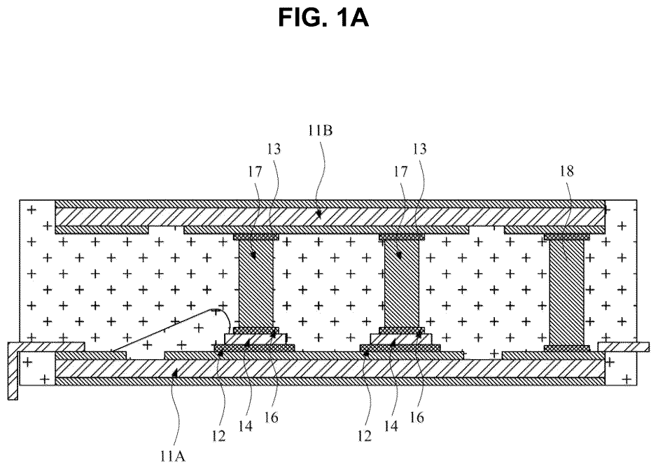

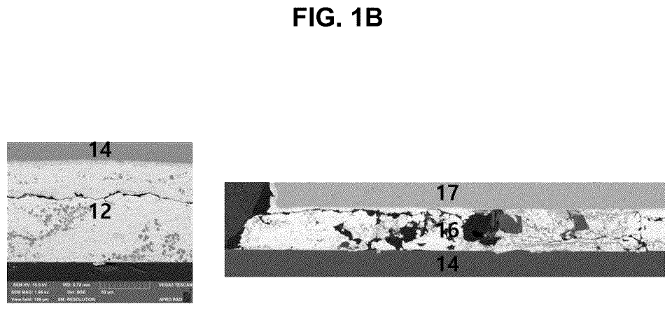

### DETAILED DESCRIPTION OF THE INVENTION

Hereinafter, embodiments of the present invention will be described in more detail with reference to the accompanying drawings.

A double-sided heat dissipation semiconductor package according to a first embodiment of the present invention includes at least one semiconductor device 130, at least one semiconductor component 140, at least one first electrical connection member 150, at least one second electrical connection member 160, a package housing 170, and at least one terminal lead 180, wherein one surface of the at least one semiconductor device 130 is bonded to a lower substrate 110, an upper substrate 120, or both lower substrate 110 and upper substrate 120 by using first bonding members 201 interposed therebetween, one surface of the at least one semiconductor component 140 is bonded to the lower substrate 110, the upper substrate 120, or both lower substrate 110 and upper substrate 120 by using fourth bonding members 204 interposed therebetween, the at least one first electrical connection member 150 is bonded to the other surface of the semiconductor device 130 by using second bonding members 202 interposed therebetween and is bonded to the lower substrate 110, the upper substrate 120, or both lower substrate 110 and upper substrate 120 by using third bonding members 203 interposed therebetween, the at least one second electrical connection member 160 is electrically connected to the semiconductor device 130, and the at least one terminal lead 180 is bonded to the lower substrate 110, the upper substrate 120, or both lower substrate 110 and upper substrate 120 by using fifth bonding members 205 interposed therebetween and is exposed to the outside of the package housing 170. Here, in bonding processes of the first bonding members 201 and the third bonding members 203, the boning temperature or bonding materials of the first bonding members 201 and the third bonding members 203 may be different from each other. Also, in bonding processes of the third bonding members 203 and the fifth bonding members 205, the boning temperature or bonding materials of the third bonding members 203 and the fifth bonding members 205 may be same as each other. Accordingly, the quality thereof may be improved.

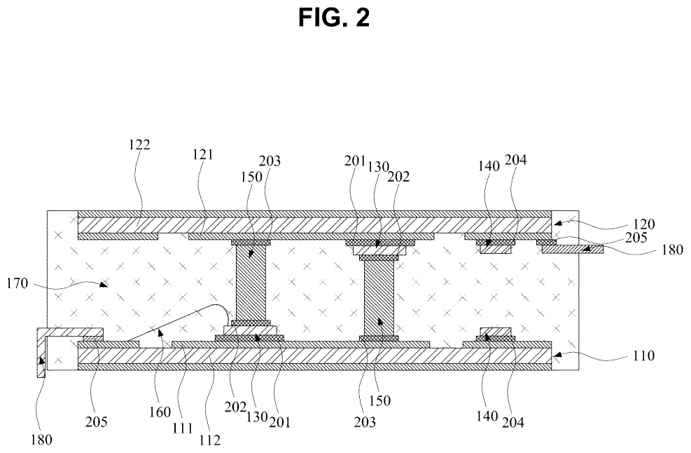

Hereinafter, the double-sided heat dissipation semiconductor package according to the first embodiment of the present invention will be described in more detail with reference to FIG. 2.

First, one or more lower substrates 110 are disposed and include at least one metal pattern 111. Also, one or more upper substrates 120 are disposed to face the lower substrates 110 and are spaced apart from the lower substrates 110, wherein the upper substrates 120 include at least one metal pattern 121.

Here, the lower substrate 110 or the upper substrate 120 may include at least one insulating layer 112 or 122 and the thickness of the metal patterns 111 and 121 may be greater than that of the insulating layers 112 and 122.

Also, the insulating layers 112 and 122 may have the thickness of 0.2 mm through 0.35 mm and may be formed of Al₂O₃, ZTA, AlN, or Si₃N₄.

In addition, the lower substrate 110 or the upper substrate 120 may be partially or entirely exposed to the surface of the package housing 170 so as to provide heat dissipation effect to the outside or may include pinfin (not illustrated) which is structurally protruded for heat dissipation so as to increase heat dissipation effect.

Next, one or more semiconductor devices 130 are included and one surfaces of the semiconductor devices 130 may be electrically bonded and connected to the lower substrate 110, the upper substrate 120, or both lower substrate 110 and upper substrate 120 by using the first bonding members 201 interposed therebetween.

Here, one surface and the other surface of the semiconductor device 130 may be formed of a metal containing 80% or more of Au or Ag and thereby, electrical conductivity may be increased.

Next, one or more semiconductor components 140 are included and one surfaces of the semiconductor components 140 may be electrically bonded and connected to the lower substrate 110, the upper substrate 120, or both lower substrate 110 and upper substrate 120 by using the fourth bonding members 204 interposed therebetween.

Here, the semiconductor component 140 may be a Negative Temperature Coefficient Thermistor (NTC) in which a resistance value is changed as a temperature increase and may check heat generation occurring due to a high current applied to the semiconductor device 130 to control the operation of the semiconductor device 130 or to stop the operation of a circuit.

Next, one or more first electrical connection members 150 are included, wherein one surfaces thereof may be bonded to the other surfaces of the at least one semiconductor device 130 by using the second bonding members 202 interposed therebetween and the other surfaces thereof may be bonded to the lower substrate 110, the upper substrate 120, or both lower substrate 110 and upper substrate 120 by using the third bonding members 203 interposed therebetween. Accordingly, the first electrical connection members 150 may support the lower substrate 110 and the upper substrate 120 and electrically connects the lower substrate 110 and the upper substrate 120 to the semiconductor devices 130.

Also, the first electrical connection members 150 may be spacers containing a hexahedral metal ingredient or metal clips in a clip form that provides an elastic force. The metal clips may be 3D clips or Z-shaped clips having various structures.

Next, one or more second electrical connection members 160 are included to be electrically connected to the at least one semiconductor device 130 and may be metal clips or bonding wires.

Here, the second electrical connection members 160 are bonding wires containing 50% or more of Al so as to provide excellent electrical conductivity and may be bonded to the semiconductor devices 130 by using an ultrasonic bonding method.

Next, the package housing 170 is molded to cover the at least one semiconductor device 130 and the at least one semiconductor component 140.

Next, one or more terminal leads 180 are included to be bonded to the lower substrate 110, the upper substrate 120, or both lower substrate 110 and upper substrate 120 by using the fifth bonding members 205 interposed therebetween and are partially or entirely exposed to the outside of the package housing 170.

Also, the terminal leads 180 may partially or entirely contain Al metal and thereby, may reduce its weight compared with use of copper so as to be weight-lightened.

In addition, the terminal leads 180 may have the surfaces partially or entirely coated with Sn so as to prevent the terminal leads 180 exposed to the outside of the package housing 170 from being oxidized and may be manufactured with a lower price compared to the price needed to plate with nickel or gold so that the cost of production may be lowered.

Here, when bonding processes are performed as the substrates 110 and 120 and the semiconductor devices 130 are bonded to each other by using the first bonding members 201 and the substrates 110 and 120 and the first electrical connection members 150 are bonded to each other by using the third bonding members 203, the bonding temperature or a bonding material of the first bonding members 201 and the third bonding members 203 may be different from each other. Accordingly, while the bonding process of the first electrical connection members 150 is performed after the bonding process of the semiconductor devices 130, the hardening temperature in the bonding process is relatively low in the third bonding members 203 compared with that of the first bonding members 201 as a following process progresses so that re-meltdown or generation of cracks may be suppressed.

Also, when bonding processes are performed as the substrates 110 and 120 and the first electrical connection members 150 are bonded to each other by using the third bonding members 203 and the substrates 110 and 120 and the terminal leads 180 are bonded to each other by using the fifth bonding members 205, the bonding temperature or a bonding material of the third bonding members 203 and the fifth bonding members 205 may be same as each other.

That is, each of the first electrical connection members 150 and the terminal leads 180 may be simultaneously bonded to the substrates 110 and 120 and thereby, the same bonding property may be maintained.

In addition, at least any one of the first bonding members 201 through the fifth bonding members 205 described above may be a solder containing Sn or an adhesive containing 55% or more of Ag or Cu.

Here, when at least any one of the first bonding members 201 through the fifth bonding members 205 is a solder, the melting temperature of the solder may be 180° C. through 500° C. When at least any one of the first bonding members 201 through the fifth bonding members 205 is an adhesive, the adhesive may be bonded by pressurizing or non-pressure sintering or epoxy included in the adhesive may be hardened to bond the adhesive.

Meanwhile, various transformation is available according to the order of the processes for bonding of the lower substrate 110 or the upper substrate 120 to the semiconductor devices 130, the semiconductor components 140, the first electrical connection members 150, the second electrical connection members 160, or the terminal leads 180. Here, the hardening temperature of the bonding members in the following process may be lower than the hardening temperature of the bonding members in the preceding process. Accordingly, when the bonding member is a solder, the solder may be prevented from being re-melted down, or when the bonding member is a sinter or epoxy, brokenness of bonding occurring due to generation of cracks may prevented.

More specifically, in a first example, the semiconductor components 140 are firstly bonded to the lower substrate 110 or the upper substrate 120 by using the fourth bonding members 204. Then, the semiconductor devices 130 are secondly bonded to the lower substrate 110 or the upper substrate 120 by using the first bonding members 201 and the first electrical connection members 150 are secondly bonded to the semiconductor devices 130 by using the second bonding members 202 at the same time. Here, the bonding materials or the bonding temperature of the first bonding members 201 and the second bonding members 202 may be same as each other and may be different from those of the fourth bonding members 204. Then, the first electrical connection members 150 are thirdly bonded to the lower substrate 110 or the upper substrate 120 by using the third bonding members 203 and the terminal leads 180 are thirdly bonded to the lower substrate 110 or the upper substrate 120 by using the fifth bonding members 205 at the same time. Here, the bonding materials or the bonding temperature of the third bonding members 203 and the fifth bonding members 205 may be same as each other and may be different from those of the first bonding members 201 and the second bonding members 202.

That is, the total 3-step bonding processes including the first bonding of the semiconductor components 140, the second bonding of the semiconductor devices 130 and the first electrical connection members 150, and the third bonding of the terminal leads 180 are performed in order. Here, the bonding members in the same bonding process may have the same bonding materials or the same bonding temperature and the bonding members in a different bonding process may have different bonding materials or the different bonding temperature. Also, the bonding members formed of each different material may respectively realize characteristics of each different bonding temperature.

Also, in a second example, the semiconductor devices 130 are firstly bonded to the lower substrate 110 or the upper substrate 120 by using the first bonding members 201 and one surfaces of the first electrical connection members 150 are firstly bonded to the semiconductor devices 130 by using the second bonding members 202 at the same time. In addition to this, the semiconductor components 140 are firstly bonded to the lower substrate 110 or the upper substrate 120 by using the fourth bonding members 204. Here, the bonding materials or the bonding temperature of the first bonding members 201, the second bonding members 202, and the fourth bonding members 204 may be same as each other. Then, the other surfaces of the first electrical connection members 150 are secondly bonded to the lower substrate 110 or the upper substrate 120 by using the third bonding members 203 and the terminal leads 180 are secondly bonded to the lower substrate 110 or the upper substrate 120 by using the fifth bonding members 205 at the same time. Here, the bonding materials or the bonding temperature of the third bonding members 203 and the fifth bonding members 205 may be same as each other and may be different from those of the first bonding members 201, the second bonding members 202, and the fourth bonding members 204.

That is, the total 2-step bonding processes including the first bonding of the semiconductor devices 130, the semiconductor components 140, and one surfaces of the first electrical connection members 150 and the second bonding of the other surfaces of the first electrical connection members 150 and the terminal leads 180 are performed in order. Here, the bonding members in the same bonding process may have the same bonding materials or the same bonding temperature and the bonding members in a different bonding process may have different bonding materials or the different bonding temperature.

In addition, in a third example, the semiconductor components 140 are firstly bonded to the lower substrate 110 or the upper substrate 120 by using the fourth bonding members 204 and the semiconductor devices 130 are firstly bonded to the lower substrate 110 or the upper substrate 120 by using the first bonding members 201 at the same time. Then, one surfaces of the first electrical connection members 150 are secondly bonded to the other surfaces of the semiconductor devices 130 by using the second bonding members 202. Here, the bonding materials or the bonding temperature of the second bonding members 202 may be different from those of the first bonding members 201 and the fourth bonding members 204. Then, the other surfaces of the first electrical connection members 150 are thirdly bonded to the lower substrate 110 or the upper substrate 120 by using the third bonding members 203 and the terminal leads 180 are thirdly bonded to the lower substrate 110 or the upper substrate 120 by using the fifth bonding members 205 at the same time. Here, the bonding materials or the bonding temperature of the third bonding members 203 and the fifth bonding members 205 may be same as each other and may be different from those of the first bonding members 201, the second bonding members 202, and the fourth bonding members 204.

That is, the total 3-step bonding processes including the first bonding of the semiconductor components 140 and the semiconductor devices 130, the second bonding of one surfaces of the first electrical connection members 150, and the third bonding of the other surfaces of the first electrical connection members 150 and the terminal leads 180 are performed in order. Here, the bonding members in the same bonding process may have the same bonding materials or the same bonding temperature and the bonding members in a different bonding process may have different bonding materials or the different bonding temperature.

Moreover, in a fourth example, the semiconductor devices 130 are firstly bonded to the lower substrate 110 or the upper substrate 120 by using the first bonding members 201. Then, one surfaces of the first electrical connection members 150 are secondly bonded to the other surfaces of the semiconductor devices 130 by using the second bonding members 202 and the semiconductor components 140 are secondly bonded to the lower substrate 110 or the upper substrate 120 by using the fourth bonding members 204 at the same time. Here, the bonding materials or the bonding temperature of the second bonding members 202 and the fourth bonding members 204 may be same as each other and may be different from those of the first bonding members 201. Then, the other surfaces of the first electrical connection members 150 are thirdly bonded to the lower substrate 110 or the upper substrate 120 by using the third bonding members 203 and the terminal leads 180 are thirdly bonded to the lower substrate 110 or the upper substrate 120 by using the fifth bonding members 205 at the same time. Here, the bonding materials or the bonding temperature of the third bonding members 203 and the fifth bonding members 205 may be same as each other and may be different from those of the second bonding members 202 and the fourth bonding members 204.

That is, the total 3-step bonding processes including the first bonding of the semiconductor devices 130, the second bonding of one surfaces of the first electrical connection members 150 and the semiconductor components 140, and the third bonding of the other surfaces of the first electrical connection members 150 and the terminal leads 180 are performed in order. Here, the bonding members in the same bonding process may have the same bonding materials or the same bonding temperature and the bonding members in a different bonding process may have different bonding materials or the different bonding temperature.

Also, the third bonding members 203 and the fourth bonding members 204 may include solder ingredients and the melting point of the third bonding members 203 may be lower than the melting point of the fourth bonding members 204. As described in the first embodiment through the fourth embodiment, the bonding process by using the fourth bonding members 204 is performed and then, the bonding process by using the third bonding members 203 is performed. Accordingly, the hardening temperature of the bonding members lowers as the following processes progress so that re-meltdown of the solders may be suppressed to increase bonding quality.

In addition, the third bonding members 203 and the fifth bonding members 205 may include solder ingredients and may have the same melting point. As described in the first embodiment through the fourth embodiment, the bonding processes by using the third bonding members 203 and the fifth bonding members 205 are simultaneously performed and thereby, the same bonding property may be maintained.

Moreover, the fifth bonding members 205 used to bond the terminal leads 180 are solder adhesives containing epoxy ingredients. After the fifth bonding members 205 and the terminal leads 180 are bonded to each other by soldering, epoxy may be included on the surfaces of the solders or in at least a part of the solder.

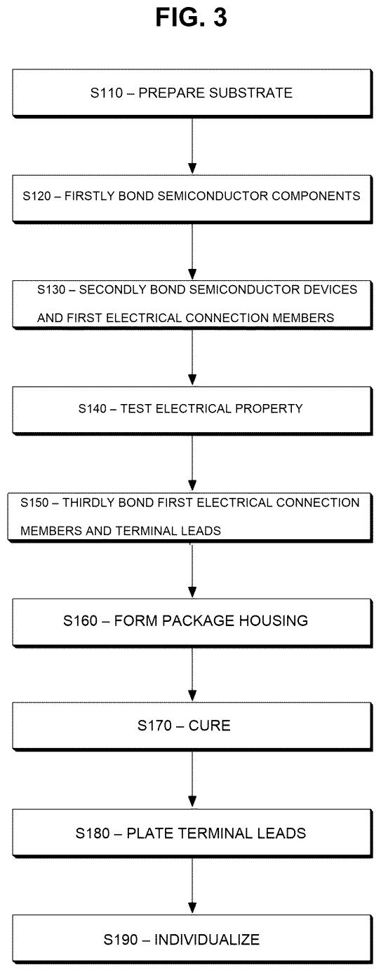

Meanwhile, FIG. 3 is a flowchart illustrating a method of manufacturing a double-sided heat dissipation semiconductor package according to a second embodiment of the present invention and relates to a method of manufacturing the double-sided heat dissipation semiconductor package described in the first example above.

That is, the method of manufacturing a double-sided heat dissipation semiconductor package according to a second embodiment of the present invention includes a first step for preparing at least one lower substrate 110 including at least one metal pattern 111 and at least one upper substrate 120 including at least one metal pattern 121 disposed to face the lower substrates 110 and spaced apart from the lower substrates 110 in S110, a second step for firstly bonding the semiconductor components 140 (for example, NTC devices) to the lower substrate 110 or the upper substrate 120 by using the fourth bonding members 204 in S120, a third step for secondly bonding the at least one semiconductor device 130 to the lower substrate 110 or the upper substrate 120 by using the first bonding members 201 and secondly bonding the at least one first electrical connection member 150 to the semiconductor devices 130 by using the second bonding members 202 at the same time in S130, a fourth step S140 for testing (middle test) electrical properties of the lower substrate 110 and the upper substrate 120 in S140, a fifth step for thirdly bonding the first electrical connection members 150 to the lower substrate 110 or the upper substrate 120 by using the third bonding members 203 and thirdly bonding the at least one terminal lead 180 to the lower substrate 110 or the upper substrate 120 by using the fifth bonding members 205 at the same time in S150, a sixth step for molding the at least one semiconductor device 130 and the at least one semiconductor component 140 by using an Epoxy Molding Compound (EMC) to form the package housing 170 in S160, a seventh step for performing curing at a predetermined temperature (for example, 150° C. through 200° C.) for more than a predetermined time (for example, three hours) in S170, an eighth step for plating the terminal leads 180 in S180, and a ninth step for individualizing a separate semiconductor package in S190.

Here, the fourth bonding members 204, the first bonding members 201 and the second bonding members 202, and the third bonding members 203 and the fifth bonding members 205 are bonded in this order. When the bonding processes of the first bonding members 201 and the third bonding members 203 are performed, the first bonding members 201 and the third bonding members 203 may have each different bonding temperature or bonding materials. When the bonding processes of the third bonding members 203 and the fifth bonding members 205 are performed, the third bonding members 203 and the fifth bonding members 205 may have the same bonding temperature or bonding materials.

That is, the first bonding of the semiconductor components 140, the second bonding of the semiconductor devices 130 and the first electrical connection members 150, and the third bonding of the terminal leads 180 are performed in order. Here, the bonding members in the same bonding process may have the same bonding materials or the same bonding temperature and the bonding members in a different bonding process may have different bonding materials or the different bonding temperature.

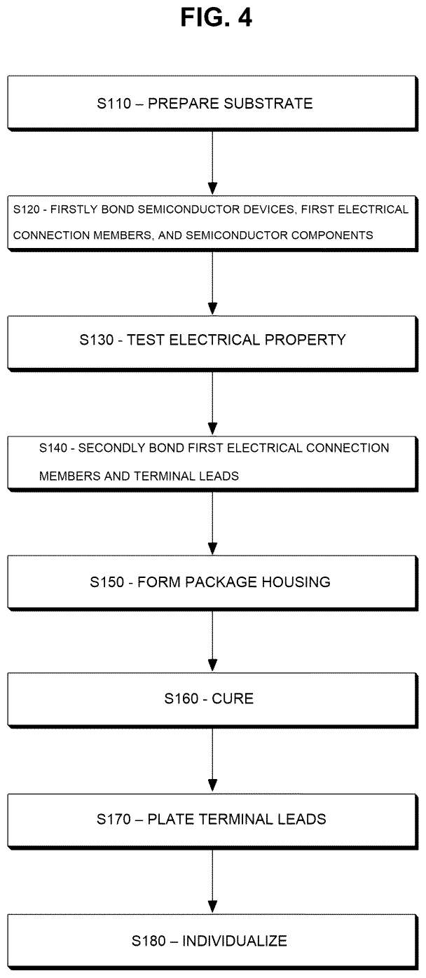

Also, FIG. 4 is a flowchart illustrating a method of manufacturing a double-sided heat dissipation semiconductor package according to a third embodiment of the present invention and relates to a method of manufacturing the double-sided heat dissipation semiconductor package described in the second example above.

That is, the method of manufacturing a double-sided heat dissipation semiconductor package according to a third embodiment of the present invention includes a first step for preparing at least one lower substrate 110 including at least one metal pattern 111 and at least one upper substrate 120 including at least one metal pattern 121 disposed to face the lower substrates 110 and spaced apart from the lower substrates 110 in S110, a second step for firstly bonding the at least one semiconductor device 130 to the lower substrate 110 or the upper substrate 120 by using the first bonding members 201, firstly bonding one surfaces of the first electrical connection members 150 to the semiconductor devices 130 by using the second bonding members 202, and firstly bonding the at least one semiconductor component 140 to the lower substrate 110 or the upper substrate 120 by using the fourth bonding members 204 at the same time in S120, a third step for testing electrical properties of the lower substrate 110 and the upper substrate 120 in S130, a fourth step for secondly bonding the other surfaces of the first electrical connection members 150 to the lower substrate 110 or the upper substrate 120 by using the third bonding members 203 and secondly bonding the at least one terminal lead 180 to the lower substrate 110 or the upper substrate 120 by using the fifth bonding members 205 at the same time in S140, a fifth step for molding the at least one semiconductor device 130 and the at least one semiconductor component 140 by using an EMC to form the package housing 170 in S150, a sixth step for performing curing at a predetermined temperature (for example, 150° C. through 200° C.) for more than a predetermined time (for example, three hours) in S160, a seventh step for plating the terminal leads 180 in S170, and an eighth step for individualizing a separate semiconductor package in S180.

Here, the fourth bonding members 204, the first bonding members 201, and the second bonding members 202 and the third bonding members 203 and the fifth bonding members 205 are bonded in this order. When the bonding processes of the first bonding members 201 and the third bonding members 203 are performed, the first bonding members 201 and the third bonding members 203 may have each different bonding temperature or bonding materials. That is, when the bonding processes of the third bonding members 203 and the fifth bonding members 205 are performed, the third bonding members 203 and the fifth bonding members 205 may have the same bonding temperature or bonding materials.

That is, the first bonding of the semiconductor devices 130, the semiconductor components 140, and one surfaces of the first electrical connection members 150 and the second bonding of the other surfaces of the first electrical connection members 150 and the terminal leads 180 are performed in order. Here, the bonding members in the same bonding process may have the same bonding materials or the same bonding temperature and the bonding members in a different bonding process may have different bonding materials or the different bonding temperature.

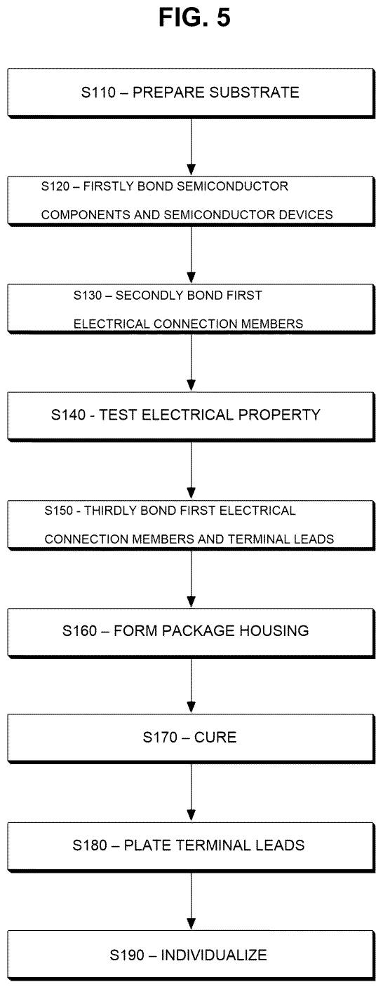

In addition, FIG. 5 is a flowchart illustrating a method of manufacturing a double-sided heat dissipation semiconductor package according to a fourth embodiment of the present invention and relates to a method of manufacturing the double-sided heat dissipation semiconductor package described in the third example above.

That is, the method of manufacturing a double-sided heat dissipation semiconductor package according to a fourth embodiment of the present invention includes a first step for preparing at least one lower substrate 110 including at least one metal pattern 111 and at least one upper substrate 120 including at least one metal pattern 121 disposed to face the lower substrates 110 and spaced apart from the lower substrates 110 in S110, a second step for firstly bonding the at least one semiconductor component 140 to the lower substrate 110 or the upper substrate 120 by using the fourth bonding members 204 and firstly bonding the at least one semiconductor device 130 to the lower substrate 110 or the upper substrate 120 by using the first bonding members 201 at the same time in S120, a third step for secondly bonding the at least one first electrical connection member 150 to the other surfaces of the semiconductor devices 130 by using the second bonding members 202 in S130, a fourth step for testing electrical properties of the lower substrate 110 and the upper substrate 120 in S140, a fifth step for thirdly bonding the other surfaces of the first electrical connection members 150 to the lower substrate 110 or the upper substrate 120 by using the third bonding members 203 and thirdly bonding the at least one terminal lead 180 to the lower substrate 110 or the upper substrate 120 by using the fifth bonding members 205 at the same time in S150, a sixth step for molding the at least one semiconductor device 130 and the at least one semiconductor component 140 by using an EMC to form the package housing 170 in S160, a seventh step for performing curing at a predetermined temperature (for example, 150° C. through 200° C.) for more than a predetermined time (for example, three hours) in S170, an eighth step for plating the terminal leads 180 in S180, and a ninth step for individualizing a separate semiconductor package in S190.

Here, the fourth bonding members 204 and the first bonding members 201, the second bonding members 202, and the third bonding members 203 and the fifth bonding members 205 are bonded in this order. When the bonding processes of the first bonding members 201 and the third bonding members 203 are performed, the first bonding members 201 and the third bonding members 203 may have each different bonding temperature or bonding materials. When the bonding processes of the third bonding members 203 and the fifth bonding members 205 are performed, the third bonding members 203 and the fifth bonding members 205 may have the same bonding temperature or bonding materials.

That is, the first bonding of the semiconductor components 140 and the semiconductor devices 130, the second bonding of one surfaces of the first electrical connection members 150, and the third bonding of the other surfaces of the first electrical connection members 150 and the terminal leads 180 are performed in order. Here, the bonding members in the same bonding process may have the same bonding materials or the same bonding temperature and the bonding members in a different bonding process may have different bonding materials or the different bonding temperature.

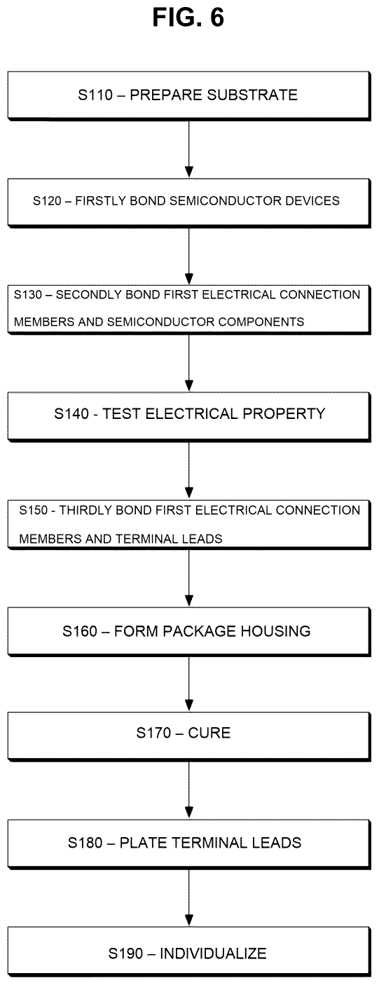

Moreover, FIG. 6 is a flowchart illustrating a method of manufacturing a double-sided heat dissipation semiconductor package according to a fifth embodiment of the present invention and relates to a method of manufacturing the double-sided heat dissipation semiconductor package described in the fourth example above.

That is, the method of manufacturing a double-sided heat dissipation semiconductor package according to a fifth embodiment of the present invention includes a first step for preparing at least one lower substrate 110 including at least one metal pattern 111 and at least one upper substrate 120 including at least one metal pattern 121 disposed to face the lower substrates 110 and spaced apart from the lower substrates 110 in S110, a second step for firstly bonding the at least one semiconductor device 130 to the lower substrate 110 or the upper substrate 120 by using the first bonding members 201 in S120, a third step for secondly bonding the at least one first electrical connection member 150 to the other surfaces of the semiconductor devices 130 by using the second bonding members 202 and secondly bonding the semiconductor components 140 to the lower substrate 110 or the upper substrate 120 by using the fourth bonding members 204 at the same time in S130, a fourth step for testing electrical properties of the lower substrate 110 and the upper substrate 120 in S140, a fifth step for thirdly bonding the other surfaces of the first electrical connection members 150 to the lower substrate 110 or the upper substrate 120 by using the third bonding members 203 and thirdly bonding the at least one terminal lead 180 to the lower substrate 110 or the upper substrate 120 by using the fifth bonding members 205 at the same time in S150, a sixth step for molding the at least one semiconductor device 130 and the at least one semiconductor component 140 by using an EMC to form the package housing 170 in S160, a seventh step for performing curing at a predetermined temperature (for example, 150° C. through 200° C.) for more than a predetermined time (for example, three hours) in S170, an eighth step for plating the terminal leads 180 in S180, and a ninth step for individualizing a separate semiconductor package in S190.

Here, the first bonding members 201, the second bonding members 202 and the fourth bonding members 204, and the third bonding members 203 and the fifth bonding members 205 are bonded in this order. When the bonding processes of the first bonding members 201 and the third bonding members 203 are performed, the first bonding members 201 and the third bonding members 203 may have each different bonding temperature or bonding materials. When the bonding processes of the third bonding members 203 and the fifth bonding members 205 are performed, the third bonding members 203 and the fifth bonding members 205 may have the same bonding temperature or bonding materials.

That is, the first bonding of the semiconductor devices 130, the second bonding of one surfaces of the first electrical connection members 150 and the semiconductor components 140, and the third bonding of the other surfaces of the first electrical connection members 150 and the terminal leads 180 are performed in order. Here, the bonding members in the same bonding process may have the same bonding materials or the same bonding temperature and the bonding members in a different bonding process may have different bonding materials or the different bonding temperature.

Therefore, according to the double-sided heat dissipation semiconductor package and the method of manufacturing the same described above, the bonding members in the same bonding process may have the same bonding materials or the same bonding temperature and the bonding members in a different bonding process may have different bonding materials or the different bonding temperature. Accordingly, while the bonding processes are sequentially performed, the bonding members may be hardened at a relatively low temperature in the following process and thereby, re-meltdown or generation of cracks may be suppressed so as to improve its quality.

According to the present invention, the bonding members in the same bonding process may have the same bonding materials or the same bonding temperature and the bonding members in a different bonding process may have different bonding materials or the different bonding temperature. Accordingly, while the bonding processes are sequentially performed, the bonding members may be hardened at a relatively low temperature in the following process and thereby, re-meltdown or generation of cracks may be suppressed so as to improve its quality.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A double-sided heat dissipation semiconductor package comprising:
at least one lower substrate comprising at least one metal pattern;
at least one upper substrate comprising at least one metal pattern disposed to face the lower substrates and spaced apart from the lower substrates;
at least one semiconductor device comprising one surface bonded to the lower substrate, the upper substrate, or both lower substrate and upper substrate by using first bonding members interposed therebetween;
at least one semiconductor component comprising one surface bonded to the lower substrate, the upper substrate, or both lower substrate and upper substrate by using fourth bonding members interposed therebetween;
at least one first electrical connection member comprising one surface bonded to the other surface of the at least one semiconductor device by using second bonding members interposed therebetween and the other surface bonded to the lower substrate, the upper substrate, or both lower substrate and upper substrate by using third bonding members interposed therebetween;
at least one second electrical connection member electrically connected to the at least one semiconductor device;
a package housing covering the at least one semiconductor device and the at least one semiconductor component; and
at least one terminal lead bonded to the lower substrate, the upper substrate, or both lower substrate and upper substrate by using fifth bonding members interposed therebetween and partially or entirely exposed to the outside of the package housing, wherein when bonding processes of the first bonding members and the third bonding members are performed, the boning temperature or bonding materials of the first bonding members and the third bonding members are different from each other and when bonding processes of the third bonding members and the fifth bonding members are performed, the boning temperature or bonding materials of the third bonding members and the fifth bonding members are same as each other.

2. The double-sided heat dissipation semiconductor package of claim 1, wherein at least any one of the first bonding members through the fifth bonding members is a solder containing Sn or an adhesive containing 55% or more of Ag or Cu.

3. The double-sided heat dissipation semiconductor package of claim 2, wherein when at least any one of the first bonding members through the fifth bonding members is a solder, the melting temperature of the solder is 180° C. through 500° C.

4. The double-sided heat dissipation semiconductor package of claim 2, wherein when at least any one of the first bonding members through the fifth bonding members is an adhesive, the adhesive is bonded by pressurizing or non-pressure sintering or epoxy included in the adhesive is hardened to bond the adhesive.

5. The double-sided heat dissipation semiconductor package of claim 1, wherein the semiconductor component is firstly bonded to the lower substrate or the upper substrate by using the fourth bonding members, the semiconductor devices are secondly bonded to the lower substrate or the upper substrate by using the first bonding members and the first electrical connection members are secondly bonded to the semiconductor devices by using the second bonding members at the same time, the bonding materials or the bonding temperature of the first bonding members and the second bonding members are same as each other and are different from those of the fourth bonding members, the other surfaces of the first electrical connection members are thirdly bonded to the lower substrate or the upper substrate by using the third bonding members and the terminal leads are thirdly bonded to the lower substrate or the upper substrate by using the fifth bonding members at the same time, and the bonding materials or the bonding temperature of the third bonding members and the fifth bonding members are same as each other and are different from those of the first bonding members and the second bonding members.

6. The double-sided heat dissipation semiconductor package of claim 1, wherein the semiconductor devices are firstly bonded to the lower substrate or the upper substrate by using the first bonding members, one surfaces of the first electrical connection members are firstly bonded to the semiconductor devices by using the second bonding members, and the semiconductor components are firstly bonded to the lower substrate or the upper substrate by using the fourth bonding members at the same time, the bonding materials or the bonding temperature of the first bonding members, the second bonding members, and the fourth bonding members are same as each other, the other surfaces of the first electrical connection members are secondly bonded to the lower substrate or the upper substrate by using the third bonding members and the terminal leads are secondly bonded to the lower substrate or the upper substrate by using the fifth bonding members at the same time, and the bonding materials or the bonding temperature of the third bonding members and the fifth bonding members are same as each other and are different from those of the first bonding members, the second bonding members, and the fourth bonding members.

7. The double-sided heat dissipation semiconductor package of claim 1, wherein the semiconductor components are firstly bonded to the lower substrate or the upper substrate by using the fourth bonding members and the semiconductor devices are firstly bonded to the lower substrate or the upper substrate by using the first bonding members at the same time, one surfaces of the first electrical connection members are secondly bonded to the other surfaces of the semiconductor devices by using the second bonding members, the bonding materials or the bonding temperature of the second bonding members are different from those of the first bonding members and the fourth bonding members, the other surfaces of the first electrical connection members are thirdly bonded to the lower substrate or the upper substrate by using the third bonding members and the terminal leads are thirdly bonded to the lower substrate or the upper substrate by using the fifth bonding members at the same time, and the bonding materials or the bonding temperature of the third bonding members and the fifth bonding members are same as each other and are different from those of the first bonding members, the second bonding members, and the fourth bonding members.

8. The double-sided heat dissipation semiconductor package of claim 1, wherein the semiconductor devices are firstly bonded to the lower substrate or the upper substrate by using the first bonding members, one surfaces of the first electrical connection members are secondly bonded to the other surfaces of the semiconductor devices by using the second bonding members and the semiconductor components are secondly bonded to the lower substrate or the upper substrate by using the fourth bonding members at the same time, the bonding materials or the bonding temperature of the second bonding members and the fourth bonding members are same as each other and are different from those of the first bonding members, the other surfaces of the first electrical connection members are thirdly bonded to the lower substrate or the upper substrate by using the third bonding members and the terminal leads are thirdly bonded to the lower substrate or the upper substrate by using the fifth bonding members at the same time, and the bonding materials or the bonding temperature of the third bonding members and the fifth bonding members are same as each other and are different from those of the second bonding members and the fourth bonding members.

9. The double-sided heat dissipation semiconductor package of claim 1, wherein the lower substrate or the upper substrate comprises at least one insulating layer and a thickness of the metal pattern is greater than a thickness of the insulating layer.

10. The double-sided heat dissipation semiconductor package of claim 9, wherein the thickness of the insulating layer is 0.2 mm through 0.35 mm.

11. The double-sided heat dissipation semiconductor package of claim 9, wherein the insulating layer is Al₂O₃, ZTA, AlN, or Si₃N₄.

12. The double-sided heat dissipation semiconductor package of claim 1, wherein the semiconductor component is a Negative Temperature Coefficient Thermistor (NTC).

13. The double-sided heat dissipation semiconductor package of claim 1, wherein the third bonding members and the fourth bonding members comprise solder ingredients and the melting point of the third bonding members is lower than the melting point of the fourth bonding members.

14. The double-sided heat dissipation semiconductor package of claim 1, wherein the third bonding members and the fifth bonding members comprise solder ingredients and have the same melting point.

15. The double-sided heat dissipation semiconductor package of claim 1, wherein the fifth bonding members used to bond the terminal leads are solder adhesives containing epoxy ingredients and epoxy is included on the surfaces of the solders or in at least a part of the solder after the fifth bonding members and the terminal leads are bonded to each other by soldering.

16. The double-sided heat dissipation semiconductor package of claim 1, wherein the second electrical connection members contain 50% or more of Al and are bonded to the semiconductor devices by using an ultrasonic bonding method.

17. The double-sided heat dissipation semiconductor package of claim 1, wherein one surfaces and the other surfaces of the semiconductor devices are formed of a metal containing 80% or more of Au or Ag.

18. The double-sided heat dissipation semiconductor package of claim 1, wherein the terminal leads partially or entirely contain Al.

19. The double-sided heat dissipation semiconductor package of claim 1, wherein the lower substrate or the upper substrate is partially or entirely exposed to the surface of the package housing.

20. The double-sided heat dissipation semiconductor package of claim 1, wherein the terminal leads have the surfaces partially or entirely coated with Sn.
